(19) United States
(12) Patent Application Publication
(10) Pub. No.: US 2014/0353805 A1
(43) Pub. Date: Dec. 4, 2014

(54) METHODS OF SEMICONDUCTOR CONTAMINANT REMOVAL USING SUPERCRITICAL FLUID

(71) Applicant: GLOBALFOUNDRIES Inc., Grand Cayman (KY)

(72) Inventors: Errol Todd RYAN, Clifton Park, NY (US); Moosung M. CHAE, Englewood Cliffs, NJ (US); Larry ZHAO, Niskayuna, NY (US); Kunaljeet TANWAR, Slingerlands, NY (US); Nicholas Vincent LICAUSI, Watervliet, NY (US); Christian WITT, Woodbridge, CT (US); Ailian ZHAO, Slingerlands, NY (US); Ming HE, Slingerlands, NY (US); Sean X. LIN, Watervliet, NY (US); Xunyuan ZHANG, Albany, NY (US)

(73) Assignee: GLOBALFOUNDRIES Inc., Grand Cayman (KY)

(21) Appl. No.: 13/903,618

(22) Filed: May 28, 2013

(51) Int. Cl. H01L 21/3105; H01L 23/00

(52) U.S. Cl. CPC H01L 21/3105; H01L 23/564
USPC 257/632; 438/476

(57) ABSTRACT

A process is provided for the removal of contaminants from a semiconductor device, for example, removing contaminants from pores of an ultra-low k film. In one aspect, a method includes: providing a dielectric layer with contaminant-containing pores and exposing the dielectric layer to a supercritical fluid. The supercritical fluid can dissolve and remove the contaminants. In another aspect, an intermediate semiconductor device structure is provided that contains a dielectric layer with contaminant-containing pores and a supercritical fluid within the pores. In another aspect, a semiconductor device structure with a dielectric layer containing uncontaminated pores is provided.

### FIELD OF THE INVENTION

The present invention generally relates semiconductor devices and to methods of removing contaminants from semiconductor devices, and more particularly, to methods of removal of contaminants from a porous dielectric film using a supercritical fluid.

### BACKGROUND OF THE INVENTION

The critical point of a substance is the temperature and pressure at which the gas and liquid forms of a fluid are in equilibrium, making it impossible to distinguish between gas and liquid phases. When the substances temperature and pressure are above the substance's critical point, a “supercritical fluid” is formed. These supercritical fluids have liquid-like densities but behave like gases. The liquid-like properties enable these fluids to dissolve materials, but the gas-like properties allow them to flow through solids like a gas.

During the semiconductor patterning process, it is common after trench etching for wet cleans, or other cleaning processes, to be performed. However, contamination in the wet clean solvent may be spread throughout the pores when the wet clean solvent flows into the pores, often resulting in the presence of residues inside the pores. When the wet clean solvent leaves the pores upon drying by evaporation, contaminants in the wet clean solvent can come out of solution and remain deposited in the pores. Currently, nothing is done to remove these contaminants. Any contaminants deposited in the pores stay and could impact the reliability of the part. The contaminants can also affect etching of the film by adding carbon to the film; for example, if you etch vias after the trenches are etched, any carbon contamination deposited in the trenches after trench etch wet clean can affect via etch rates.

Accordingly, a need exists for a process of removing contaminants from pores after the etching and cleaning processes during fabrication.

### BRIEF SUMMARY

Advantages are provided through the provision, in one aspect, of a method which includes: obtaining a dielectric layer with contaminant-containing pores and exposing the dielectric layer to a supercritical fluid.

In another aspect, an intermediate semiconductor device structure is provided that contains a dielectric layer with pores containing contaminants and a supercritical fluid within the pores.

In another aspect, a semiconductor device structure with a dielectric layer containing pores is provided; the pores are decontaminated by exposure to a supercritical fluid.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts one embodiment of a process for removing contaminants from a semiconductor, in accordance with one or more aspects of the present invention.

FIG. 2 depicts a porous ultra-low k layer illustrating one embodiment of a semiconductor device structure, in accordance with one or more aspects of the present invention.

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure.

Reference is made below to the drawings, which are not drawn to scale for ease of understanding, wherein the same reference numbers used throughout different figures designate the same or similar components.

Generally stated, disclosed herein is an enhanced method for removing contaminants from a dielectric layer, for instance, a porous ultra-low k film. Non-limiting examples of these films include various porous spin-on organosilicate glass films, such as sol-gel silicates and methylsilsesquioxanes, or plasma-enhanced chemical vapor deposition (PECVD) deposited porous films, such as Novellus Corel and Applied Materials Black Diamond. The method includes, in one aspect, obtaining a dielectric layer with pores which contain contaminants, and exposing the dielectric layer to a supercritical fluid. In another aspect, an intermediate semiconductor device structure is provided that contains a dielectric layer with pores containing contaminants and a supercritical fluid within the pores. In another aspect, a semiconductor device structure with a dielectric layer containing pores is provided these pores are decontaminated due to their exposure to a supercritical fluid.

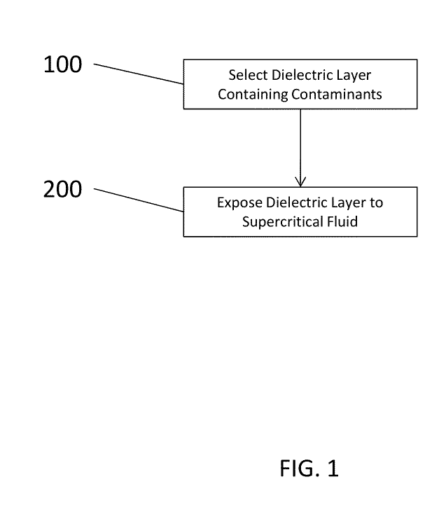

A process overview of one embodiment of the contaminant removal method is disclosed herein and depicted in FIG. 1. As shown in FIG. 1, the contaminant removal process starts with obtaining a dielectric layer containing contaminants 100. The dielectric layer may be a porous ultra-low k film that contains pores with contaminants (also referred to herein as “residues”) deposited in the pores. The contaminants could result, for instance, from the trench etch and solvents used in the cleaning processes. Contamination in the pores from any source, including wet clean, could potentially be removed, provided that the contaminants are soluble in the supercritical fluid being used. This contaminated dielectric layer is then exposed to a supercritical fluid 200 The supercritical fluid can flow through the pores of the dielectric layer, dissolving the contaminants contained within the pores. The supercritical fluid is able to leave the pores like a vapor while the contaminants remain dissolved in it. In this manner, the contaminants are removed from the pores with the removal of the supercritical fluid.

In one non-limiting example, a semiconductor device structure is placed into a pressure chamber held at (or above) the critical temperature needed for the desired gas mixture. The gas mixture, (carbon dioxide and a cosolvent, for example) would then flow into the pressure chamber until the critical pressure is reached. At the point that both the critical temperature and critical pressure are reached, the gas mixture becomes a supercritical fluid. This gas mixture (i.e., the supercritical fluid) is then flowed continuously over the semiconductor device structure for a time necessary to remove the contaminants from the pores. The gas mixture pressure is then reduced such that the gas loses its supercritical fluid properties, emptying the chamber. The semiconductor device structure can then be removed from the pressure chamber.

The supercritical fluids to be used must possess critical points of temperatures and pressures that are compatible with semiconductor back end of line processing. Further, the supercritical fluid chosen should have the capability to dissolve the contaminants in the pores. In some embodiments, the supercritical fluid has a critical temperature between 100K and 600K and a critical pressure between 3 MPa and 12 MPa. Although higher pressure may be more costly to deal with, it is envisioned that higher temperatures and/or pressures may be desired. In some embodiments, the supercritical fluid has a critical temperature between 150K and 375K. In other embodiments, the supercritical fluid has a critical temperature between 175K and 325K. In some embodiments, the supercritical fluid has a critical pressure between 4 MPa and 8 MPa. Non-limiting examples of supercritical fluids to be used include: carbon dioxide, methane, ethane, propane, ethylene, propylene, ammonia, nitrous oxide, xenon, krypton, butane, pentane, methanol, ethanol, acetone. In some embodiments, the supercritical fluid is carbon dioxide. In some embodiments, various cosolvents could be added to enhance the solubility of the supercritical fluid. This critical point will be different for the mixture. The solvation properties of single component or multi-component supercritical fluids may be tuned as desired by altering the pressure and temperature.

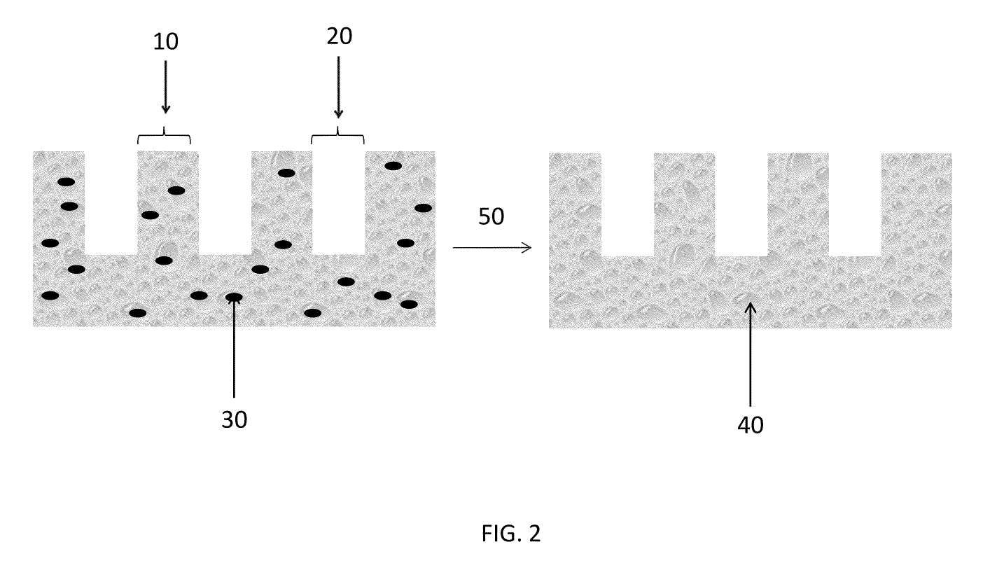

FIG. 2 illustrates one embodiment of a semiconductor device structure described herein. A porous ultra-low k dielectric layer 10 is etched, resulting in trenches 20 being formed in the dielectric layer 10. Wet clean, or other processes, after the trench etch results in residues, or contaminants, 30 being left inside the pores of the dielectric layer. Exposure of these contaminated pores to a supercritical fluid 50, which can flow throughout the pores of the dielectric layer 10, results in the dissolution of the contaminants 30 in the supercritical fluid 50 and, thus, their elimination upon the removal of the supercritical fluid 50. This results in decontaminated pores 40 of the dielectric layer 10. The term “decontaminated pore” is meant to indicate a pore that has been exposed to a supercritical fluid, that is, a supercritical fluid-cleaned pore. “Decontaminated” does not necessarily mean that the pore is completely free of contaminants.

Another aspect of the invention includes an intermediate semiconductor device structure. This intermediate semiconductor device structure has a dielectric layer containing pores with contaminants, as described above. The intermediate semiconductor device structure also includes a supercritical fluid within its pores. In some embodiments, the contaminants will be dissolved within the supercritical fluid contained in the pores.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A method, comprising;
removing contaminants from a semiconductor device, said removing contaminants comprising:
obtaining a dielectric layer comprising pores, wherein said pores contain contaminants; and
exposing said dielectric layer to a supercritical fluid.

2. A method according to claim 1, wherein said supercritical fluid has a critical temperature between 100K and 600K and a critical pressure between 3 MPa and 12 MPa.

3. A method according to claim 2, wherein said supercritical fluid has a critical temperature between 150K and 375K.

4. A method according to claim 3, wherein said supercritical fluid has a critical temperature between 175K and 325K.

5. A method according to claim 2, wherein said supercritical fluid has a critical pressure between 4 MPa and 8 MPa.

6. A method according to claim 1, wherein said supercritical fluid is selected from of the group consisting of carbon dioxide, methane, ethane, propane, ethylene, propylene, ammonia, nitrous oxide, xenon, krypton, butane, and pentane.

7. A method according to claim 6, wherein said supercritical fluid is carbon dioxide.

8. An intermediate semiconductor device structure comprising:
a dielectric layer comprising pores, wherein said pores contain contaminants; and
a supercritical fluid within said pores.

9. An intermediate semiconductor device structure according to claim 8, wherein said supercritical fluid is selected from the group consisting of carbon dioxide, methane, ethane, propane, ethylene, propylene, ammonia, nitrous oxide, xenon, krypton, butane, and pentane.

10. An intermediate semiconductor device structure according to claim 9, wherein said supercritical fluid is carbon dioxide.

11. A semiconductor device structure comprising a dielectric layer comprising pores, said pores being decontaminated by exposure to a supercritical fluid.

12. A semiconductor device structure according to claim 11, wherein the supercritical fluid is selected from the group consisting of carbon dioxide, methane, ethane, propane, ethylene, propylene, ammonia, nitrous oxide, xenon, krypton, butane, and pentane.

13. A semiconductor device structure according to claim 12, wherein the supercritical fluid is carbon dioxide.
